(19) United States
(12) Patent Application Publication
(10) Pub. No.: US 2026/0219316 A1
(43) Pub. Date: Jul. 30, 2026

(54) METHODOLOGY OF USING CHIP-TO-CHIP BYPASS PATH FOR MULTI-DIE STRUCTURAL TEST

(71) Applicant: NVIDIA Corporation, Santa Clara, CA (US)

(72) Inventors: Xuehui Zhang, Palo Alto, CA (US); Shantanu Sarangi, Saratoga, CA (US); Mahmut Yilmaz, Los Altos Hills, CA (US); Lei Lin, Santa Clara, CA (US); Jue Wu, Los Gatos, CA (US); Vishai Agarwal, Santa Clara, CA (US); Jason Lee, Los Altos, CA (US); Ish Chadha, Los Altos, CA (US)

(21) Appl. No.: 19/041,195

(22) Filed: Jan. 30, 2025

(51) Int. Cl. G01R 31/28; G01R 31/317

(52) U.S. Cl. CPC G01R 31/2896; G01R 31/2868; G01R 31/31713

(57) ABSTRACT

A multi-dielet module is disclosed. In one embodiment, the module comprises an interposer and a substrate. The interposer is connected to at least one I/O dielet and at least one non-I/O dielet using micro-bump interconnect structures. The substrate is connected to the interposer using C4 bumps on one surface of the substrate and BGA interconnect structures on another. The at least one I/O dielet is configured to allow structural/scan test data from an external source to be communicated through the substrate and interposer to test I/Os of the at least one I/O dielet. The at least one I/O dielet is configured to allow the structural/scan test data to be communicated from the at least one I/O dielet to the that at least one non-I/O dielet using a chip-to-chip (C2C) interface and the micro-bump interconnect structures of the at least one I/O dielet and the at least one non-I/O dielet.

### TECHNICAL FIELD

This application is directed, in general, to a method and hardware for communicating structural test data among multiple dielets of a multi-dielet module and, more specifically, to a method and hardware for communicating structural test data between dielets using a chip-to-chip (C2C) interface.

### BACKGROUND

As chip functionality continues to increase significantly, the prospect of building the entire chip functionality on a single die becomes impractical due to such factors as yield loss and device limitations. The larger the die, the greater the yield loss, leading to a current industry trend of employing several smaller dies, e.g., “dielets,” and integrating multiple dielets into a single package or module, reducing yield loss based on smaller dielet sizes. These dielets can communicate with one another through a chip-to-chip (C2C) interface. The C2C interface allows for functional data to be passed between dielets when the module is in operation. To structurally test a single package/module that comprises multiple dielets structural test data, e.g., scan data from external Automatic Test Equipment (ATE), to be passed to each dielet. One traditional method employed is for each dielet to transmit and receive the scan data is through the use of test input/outputs (test I/Os) on the dielet.

One issue with this increased use of dielets is that some dielets do not have enough area to provide space the test I/Os or for conventional attachment structures, e.g., ball-grid array (BGA) balls, that attach the dielet to another layer of the above-described single package/module. These dielets without sufficient space for test I/Os and conventionally sized BGA balls can inhibit their ability to use structural/scan test data (creating “I/O-limited” or “land-locked” dielets), posing a significant challenge to testing the single package/module.

### SUMMARY OF THE DISCLOSURE

In one aspect, a method to perform structural test of a multi-dielet module that includes both I/O and non-I/O dielets is disclosed. In one embodiment, the method comprises communicating test data from an external source to at least one I/O dielet using test I/Os and ball-grid array (BGA) interconnect structures and then communicating the structural/scan test data from the at least one I/O dielet to the non-I/O dielets using a chip-to-chip (C2C) interface and micro-bump interconnect structures.

In another aspect, a multi-dielet module is disclosed. In one embodiment, the multi-dielet module comprises at least one I/O dielet, at least one non-I/O dielet, an interposer, and a substrate. One side of the interposer is connected to the at least one I/O dielet and the at least one non-I/O dielet using micro-bump interconnect structures. The substrate is connected to another side of the interposer using C4 bumps on one surface of the substrate, wherein the substrate includes BGA interconnect structures on another surface of the substrate. The at least one I/O dielet is configured to allow structural/scan test data from an external source to be communicated through the substrate and interposer to test I/Os of the at least one I/O dielet. The at least one I/O dielet is configured to allow the structural/scan test data from the external source to be communicated between the at least one I/O dielet and the at least one non-I/O dielet using a chip-to-chip (C2C) interface of the at least one I/O dielet and the micro-bump interconnect structures of the at least one I/O dielet.

In still another aspect, a non-I/O dielet is disclosed. In one embodiment, the non-I/O dielet comprises a plurality of bond pads and a plurality of chip-to-chip (C2C) interfaces. The plurality of bond pads is configured to receive interconnect structures. The plurality of C2C interfaces is configured to communicate with at least one other non-I/O dielet or at least one I/O dielet, wherein structural/scan test data is communicated between the at the least one I/O dielet and the at least one other non-I/O dielet using at least one of the C2C interfaces and the interconnect structures.

In yet another aspect, an I/O dielet is disclosed. In one embodiment, the I/O dielet comprises a plurality of bond pads, a plurality of test I/Os, a plurality of other bond pads, and a plurality of chip-to-chip (C2C) interfaces. The plurality of bonds pads is configured to receive ball grid array (BGA) interconnect structures. Each of the plurality of test I/Os is connected to a corresponding one of the plurality of bond pads configured to receive the BGA interconnect structures. The plurality of other bond pads are configured to receive micro-bump interconnect structures. Each of the plurality of C2C interfaces is connected to a corresponding one of the other bond pads configured to receive the micro-bump interconnect structures and are configured to communicate with at least one non-I/O dielet. The structural/scan test data is received by the test I/Os of the I/O dielet. The plurality of C2C interfaces communicate the structural/scan test data to the at least one non-I/O dielet using at least one of the C2C interfaces and the micro-bump interconnect structures.

### BRIEF DESCRIPTION OF THE DRAWINGS

Reference is now made to the following descriptions taken in conjunction with the accompanying drawings, in which:

FIG. 1 illustrates a cross section of an example of a multi-dielet module according to principles of the disclosure;

FIG. 2 illustrates an example of a block diagram of a multi-dielet module configured to communicate with external automated test equipment (ATE) according to principles of the disclosure;

FIG. 3 illustrates an example of a block diagram of another multi-dielet module configured to communicate with external automated test equipment (ATE) according to principles of the disclosure;

FIG. 4 illustrates an example of signal paths for structural/scan test data among dielets of a multi-dielet module where each dielet has its own standalone JTAG network according to principles of the disclosure; and

FIG. 5 illustrates a flow diagram of an example of a method of performing a structural/scan test of a multi-dielet module according to principles of the disclosure.

### DETAILED DESCRIPTION OF THE DISCLOSURE

In the above-described use of dielets, each dielet will include functionality specific to that dielet that is different from specific functionality for other dielets. Typically, the selection of functionality for a specific dielet is based on the probability of reuse of the specific functionality of the dielet. Thus, different dielets will be fabricated using conventional techniques on different silicon wafers. That is, each silicon wafer (or a batch of silicon wafers) will only have one of the different dielets replicated thereon.

As noted above, some dielets to be used in the single package/module do not have area for test I/Os and corresponding bond pads configured to receive the BGA interconnect structures. These dielets are termed “non-I/O dielets” and their lack of test I/Os and BGA interconnect structures means that these non-I/O dielets cannot be structurally tested during package-level structural testing. However, in some embodiments, these non-I/O dielets include special I/Os that can be used for wafer-level structural testing but these special I/Os are not balled out for package-level structural testing.

Dielets used in the single package/module that do have enough space for the test I/Os and BGA interconnect structures will be tested through the test I/Os (or, in some embodiments, utilizing a different interface, e.g., a peripheral component interconnect express, e.g., PCIE, interface). The above-described single package/module can include multiple non-I/O dielets but must include at least one I/O dielet. The at least one I/O dielet allows for, inter alia, structural/scan test data to be externally input into the I/O dielet from, e.g., external ATE, using the test I/Os and conventional BGA ball interconnect structures during package-level structural testing.

In the disclosed method and hardware, there are two types of test I/O structures on the I/O dielet for the structural/scan data as disclosed below. One type of test I/O structure is a general purpose test I/O (e.g., GPIO). The other type of test I/O structure is a high-speed test I/O. The structural/scan test data can be externally input into the I/O dielet using the GPIO and/or the high-speed test I/O. To pass the externally generated scan data to the non-I/O dielets on the single package/module during the package-level structural testing, the above-described C2C interface is used. Here, the non-I/O dielets communicate with both other non-I/O dielets and I/O dielets (of the single package/module) using the C2C interface. This externally generated scan data is typically communicated from the I/O dielet(s) to the non-I/O dielet(s) during package-level structural testing. Since there is no room on these non-I/O dielets to use test I/Os and conventional BGA ball interconnect structures, micro-bump interconnect structures are used instead.

Micro-bumps are one of many interconnect structures used in three-dimensional (3D) packaging. Micro-bumps are typically formed with a copper (Cu) pillar topped by a solder cap (usually tin-silver (SnAg)). Micro-bumps are also sometimes referred to as “C2” (chip connection) bumps. Micro-bumps have a height from approximately 20-50 μm in height with pitch spacing of approximately 30-60 μm. Another 3D interconnect structure is commonly called a controlled-collapse chip connection (“C4”) bump. C4 bumps are typically a solder (SnAg) ball formed over a Cu base. C4 bumps have a height from approximately 100-125 μm with a pitch spacing of approximately 150-225 μm.

An example of a 3D packaging structure used with the above-described dielets is a Chip on Wafer Substrate with silicon interposer (CoWoS®-S). CoWoS technology is an advanced packaging technology that involves directly packaging multiple processor chips (e.g., system-on-a-chip, or SoCs) on a silicon interposer. These chips, including the dielets described above, are vertically connected through through-silicon vias (TSVs) on the interposer, forming a highly integrated system package. This silicon interposer is then integrated onto a substrate that can be formed from, e.g., a ceramic or organic material. This method significantly shortens a connection distance between chips (dielets), enhancing data transfer speed, reducing latency, and improving overall system performance. In some embodiments, the dielets are attached to the silicon interposer using the above-described C2 micro-bumps and/or C4 bumps. In some embodiments, the silicon interposer is attached to a substrate using, e.g., that above-described C4 bumps. In some embodiments, the substrate is attached to, e.g., a printed circuit board (PCB) using, e.g., the above-described BGA ball interconnect structures.

As noted above, the C2C interface is used not only to pass structural/scan data between dielets but also to pass functional data between the dielets when the dielets and corresponding single package is in normal operation. When passing functional data between dielets, the C2C interface operates in a functional mode (e.g., transferring dozens of gigabytes of data per second using differential-ended signals). When passing structural/scan test data, the C2C interface operates in a bypass mode. Thus, both the I/O and non-I/O dielets must be able to discern when the data to be passed between dielets is either scan test data in the bypass mode or functional data in the functional mode.

During package-level structural test, e.g., testing of an assembled single package with multiple dielets located thereon, the I/O dielets receive ATE structural test data and the non-I/O dielets receive/send the structural test data from/to the I/O dielet through the C2C in a bypass mode. As disclosed herein, externally generated test data (from, e.g., ATE) is used to structurally test the single package/module across both I/O and non-I/O dielets.

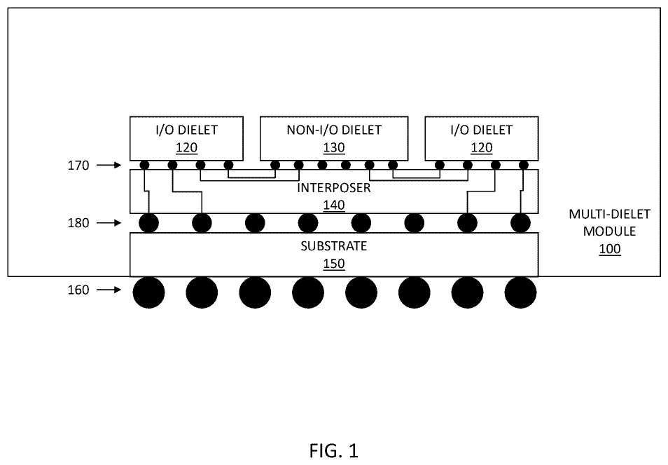

Referring to the drawings, specifically FIG. 1, a cross section of an example of a multi-dielet module 100 according to principles of the disclosure is shown. Multi-dielet module includes I/O dielets 120, non-I/O dielet 130, interposer 140, substrate 150, BGA interconnect structures 160, micro-bumps (C2 bumps) 170, and C4 bumps 180. In some embodiments, micro-bumps 170 and C4 bumps 180 are as described above. While FIG. 1 depicts two I/O dielets 120 and one non-I/O dielet 130 attached to an interposer, e.g., interposer 140 of multi-dielet module 100, any number of I/O dielets and non-I/O dielets may be attached to the interposer. In some embodiments, interposer 140 is a silicon interposer formed from silicon. I/O dielets 120 and non-I/O dielet 130 are attached to one side of interposer 140 using micro-bumps 170. Another side of interposer 140 is attached to one side of substrate 150 using C4 bumps 180. In some embodiments, interconnect structures other than C4 bumps are used to attach interposer 140 to the one side of substrate 150. In some embodiments, substrate 150 is formed from a ceramic material or an organic material. BGA interconnect structures 160 are attached to another side of substrate 150.

As depicted in FIG. 1, I/O dielets 120 communicate with non-I/O dielet 130 via micro-bumps 170 and interposer 140. As disclosed below, this communication between I/O dielets 120 and non-I/O dielets 130 utilize the above-disclosed C2C interface. Also as depicted in FIG. 1, I/O dielets communicate with substrate 150 via micro-bumps 170, interposer 140, and C4 bumps 180. As disclosed below, this communication between I/O dielets 120 and substrate 150 utilize the above-disclosed test I/Os (not shown). However, as depicted in FIG. 1, non-I/O dielet 130 does not communicate directly to substrate 150 for the reasons given above, i.e., that non-I/O dielet 130 does not have enough area to provide space for the above-disclosed test I/Os or the above-disclosed conventional attachment structures, e.g., ball-grid array (BGA) balls.

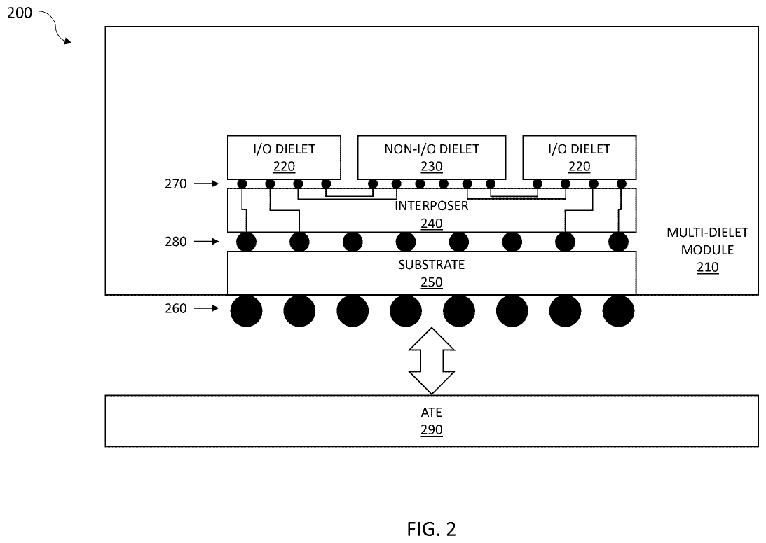

FIG. 2 illustrates a block diagram 200 of a multi-dielet module 210 configured to communicate with external automated test equipment (ATE) 290 according to principles of the disclosure. Multi-dielet 210 is similar to multi-dielet module 100 of FIG. 1 in that it includes I/O dielets 220, non-I/O dielet 230, interposer 240, substrate 250, BGA interconnect structures 260, micro-bumps (C2 bumps) 270, and C4 bumps 280. One side of substrate 250 is attached to ATE 290 utilizing BGA interconnect structures 260. In some embodiments, substrate 250 is attached to a printed circuit board (PCB) of ATE 290. In the embodiment of block diagram 200, I/O dielets 220 can communicate with external ATE 290 through interposer 240 utilizing micro-bumps 270 and substrate 250 utilizing C4 bumps 280 and BGA interconnect structures 260. In some embodiments I/O dielets 220 communicate with external ATE 290 using test I/Os of I/O dielets 220 (not shown). In order for non-I/O dielet 230 to communicate to external ATE 290, non-I/O dielet must first communicate with I/O dielets 220 using the above-disclosed C2C interface thereon (not shown) via micro-bumps 270 and then with external ATE 290 (through interposer 240 utilizing micro-bumps 270 and substrate 250 utilizing C4 bumps 280 and BGA interconnect structures 260). In some embodiments, data communicated is structural test data, including package-level structural test data.

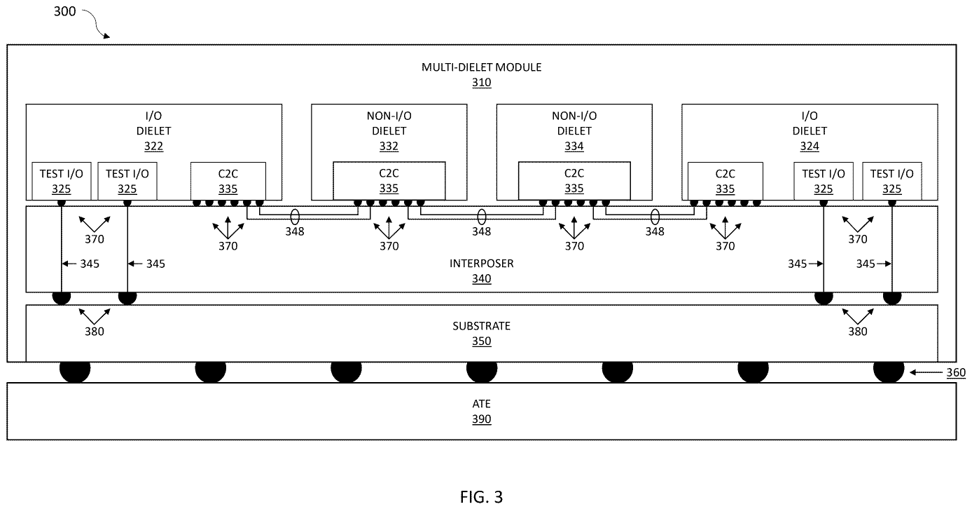

FIG. 3 illustrates an example of a block diagram 300 of a multi-dielet module 310 configured to communicate with external automated test equipment (ATE) 290 according to principles of the disclosure. Block diagram 300 is similar to block diagram 200 depicted in FIG. 2. Multi-dielet module 310 is similar to multi-dielet module 210 depicted in FIG. 2 in that it includes I/O dielets 322/324, non-I/O dielets 332/334, interposer 340, substrate 250, BGA interconnect structures 360, micro-bumps (C2 bumps) 370, and C4 bumps 380. In the example block diagram 300, multi-dielet module 310 includes two I/O dielets 322/324 and two non-I/O dielets 332/334. Of course, multi-dielet module 310 could include any number of I/O dielets and non-I/O dielets. As disclosed above and depicted in block diagram 300, I/O dielets 322/324 and non-I/O dielets 332/334 utilize micro-bumps 370 to attach to one side of an interposer, e.g., interposer 340. Micro-bumps 370 are utilized to facilitate communication between non-I/O dielets, e.g., non-I/O dielet 332, and other non-I/O dielets, e.g., non-I/O dielets 334, as well as to facilitate communication between non-I/O dielets, e.g., non-I/O dielets 332/334, and I/O dielets, e.g., I/O dielets 322/324. Interposer 340 utilizes C4 bumps to attach to one side of a substrate, e.g., substrate 350, and substrate 350 utilizes BGA interconnect structures on another side of substrate 350, e.g., BGA interconnect structures 360 to attach substrate 350 multi-dielet module 310 to external ATE, e.g., external ATE 390 (in some embodiments a PCB of external ATE 390).

I/O dielets 322/324 communicate with external ATE 290 using test I/Os 325 of I/O dielets 322/324 via a path that includes micro-bumps 370 of multi-dielet module 310, interposer via 345 of interposer 340, C4 bumps 380 of interposer 340, substrate 350, and BGA interconnect structures 360 of substrate 350. In order for non-I/O dielet 332/334 to communicate to external ATE 390, non-I/O dielet 332/334 must first communicate with I/O dielets 322/324 using C2C interfaces 335 of non-I/O dielet 332/334 and I/O dielet 322/324 (as disclosed above) via micro-bumps 370 of I/O dielet 322/324 and non-I/O dielet 332/334 and interconnects 348 of interposer 340 and then with external ATE 390 as describe above. In some embodiments, data communicated is structural test data, including package-level structural test data.

The I/O dielet, e.g., I/O dielets 120/220/322/324, perform a crucial role by receiving specific set of scan input data. This input data can be sourced from either a tester, e.g., external ATE 290/390, through test I/Os, e.g., test I/Os 325 or a host system through a PCIE interface (not shown). The selection of the interface to be used by the I/O dielet typically depends a multiplexer (MUX) which acts as a switch that enables a choice between the two interfaces. This flexibility allows for efficient data transfer and adaptability based on specific requirements of the dielet design and testing process.

During wafer-level test, all scan components in the I/O dielet, such as pipeline flops and scan wrappers (not shown), are self-contained. A scan network is formed by configuring the I/O dielet (e.g., setting internal_scan=1). When the non-I/O dielet is configured similarly (e.g., internal_scan=1), the scan components within the non-I/O dielet are daisy-chained separately. This configuration establishes self-contained scan networks within the non-I/O dielet. Each of these distinct scan networks operates independently of other dielets (and the rest of the multi-dielet module). This isolation facilitates efficient testing and data movement during the wafer-level test, ensuring accuracy and effectiveness of the test process for each individual dielet.

During package-level testing, the I/O dielets and non-I/O dielets are configured differently (e.g., setting internal_scan=0). Here, a scan bus travels through the scan network inside the I/O dielet and reaches the non-I/O dielet through a C2C bypass path. The bypass path of the C2C interface forwards scan data and a scan clock from the I/O dielet to the non-I/O dielet. Assume (1) there is an n-bits wide scan bus that needs to be forwarded from the I/O dielet to the non-I/O dielet and (2) each link in the C2C interface has a capacity to forward m-bits of scan data (where the value of m depends on specific characteristics of the C2C interface). To accommodate the entire n-bits of scan data, k C2C links are needed where k is calculated as k=rounding up (n/m). This ensures that the scan data can travel from the I/O dielet to the non-I/O dielet efficiently. It is important to note that the scan bus in the I/O dielet and the non-I/O dielet does not necessarily have to be the same width, i.e., they can have different widths as long as n is set a to minimum value between a scan bus width for the I/O dielet and a scan bus width for the non-I/O dielet. This flexibility allows for adaptability in design and enables efficient data forwarding between the dielets.

Each C2C link forwards one copy of the scan clock (SCAN_CLK) from the I/O dielet to the non-I/O dielet along with the scan data. One of the forwarded scan clocks is used as a local scan clock in the non-I/O dielet. This local scan clock drives the entire scan network in the non-I/O dielet. Each C2C link acts like pipeline flops to the scan network. A de-skew FIFO (not shown) is used to take care of clock domain crossing (CDC) issues between a different forwarded clock domain and local scan clock domain. After the de-skew FIFO, all scan components in the non-I/O dielet are in the local scan clock domain.

Since the non-I/O dielet does not have test I/Os (for the reasons disclosed above), two MUXes are controlled by the internal (local) scan signal (clock). The first MUX is responsible for selecting the scan data from the C2C bypass path (instead of from a test I/O). By selecting data from the C2C bypass path, the non-I/O dielet can receive the scan data forwarded from the I/O dielet, enabling efficient testing and data movement in the dielet. The second MUX is utilized to select the scan clock signal (SCAN_CLK) from the C2C bypass path (rather than from a test I/O), allowing the non-I/O dielet to synchronize its local scan clock domain with the forwarded scan data from the I/O dielet.

Similar to the path from the I/O dielet to the non-I/O dielet, scan data travels from one non-I/O dielet to a second non-I/O dielet through the C2C bypass path. The number of C2C links used may vary, depending on specific designs and requirements. Once the scan data reaches the second non-I/O dielet, it passes through all scan components in the second non-I/O dielet including pipeline flops, scan wrappers, and any other relevant elements necessary for scan testing in the second non-I/O dielet. Then scan data is directed back to the first non-I/O dielet through the C2C bypass path. Similarly, each C2C interface forwards one copy of the scan clock from the second non-I/O dielet back to the first non-I/O dielet along with the scan data. A de-skew FIFO in a receiver (RX) side of the first non-I/O dielet handles CDC issues between the local scan clock domain in the first non-I/O dielet and the forward scan clock domain coming from the second non-I/O dielet. Note that the forwarded clock from the second non-I/O dielet is only used by the de-skew FIFO in the first non-I/O dielet.

Once the scan data reaches back to the first non-I/O dielet, it passes through all of the scan components within the first non-I/O dielet and then is directed back to the I/O dielet through the C2C bypass path. The I/O dielet sends the scan data to the external ATE for results analysis through either the test I/Os or PCIE interface of the I/O dielet, as disclosed above. This forms a circular path that allows the scan data to be continuously tested and propagated between the I/O dielet, first non-I/O dielet, and second non-I/O dielet. Moreover, the first non-I/O dielet has the capability to forward the scan data to multiple other dielets using a similar C2C bypass path, provided that the scan networks in those dielets are daisy-chained together.

In a typical multi-dielet module when the dielets are in their functional mode, their respective C2C interfaces are usually working in a high-speed mode, which can transfer a dozen gigabytes per second with differential-ended signals. However, most of the logic in the C2C interface to be used during structural test in the bypass mode cannot work in the functional (high speed) mode. The bypass mode is a separate mode supported by the C2C interface, which allows the C2C interface to transfer slow-speed data while other logic is under test. The C2C bypass structure does not require C2C functional clock logic, it only needs the forwarded scan clock (disclosed above) to work with very minimal logic. The C2C bypass structure acts like pipeline flops and can be modeled as pipeline flops in an electronic design tool (EDT) which recognizes the C2C bypass structure during pattern generation. All of the C2C links is the same C2C interface act like the same stage of pipeline flops. The timing relationship between the scan clock and the scan data are maintained after crossing the C2C interface and they are timed synchronously on C2C bricks in the C2C bypass structure.

By default, the C2C interface is in the functional mode and needs to be programmed to work in bypass mode. Joint test action group (JTAG) (or other types of methods which are available before scan test) can be used to execute this programming. The C2C functional logic in the C2C interface has its own scan wrapper, which is daisy-chained with other scan components in the scan network. Therefore, C2C functional logic can be tested along with other dielets simultaneously when the C2C interface is in bypass mode. C2C bypass logic is tested by a scan loop-back test. Once the C2C bypass is proven to be working, it will be used for scan test and other purposes.

Each dielet has a clock MUX to select a different clock source based on a test mode (as disclosed above). During wafer-level testing, the scan clock from a test I/O is selected and can be used as a global scan clock which drives all scan components in the I/O dielet. If an I/O dielet has multiple test I/O groups, each test I/O group must have one scan clock along with scan data. A scan clock from one of the test I/O groups will be used as the global scan clock. A de-skew FIFO in the I/O dielet is used to take care of CDC between a local I/O clock group domain and the global scan clock domain as disclosed above. During package-level testing, the I/O dielet can used a scan clock from the test I/O. A non-I/O dielet may or may not have a clock source that is generated in the test I/O from the I/O dielet. If the non-I/O does not have a clock source from the test I/O from the I/O dielet, one of the forwarded clocks from the C2C bypass paths will be selected as the global scan clock in the non-I/O dielet.

As disclosed above, there are two types of test I/Os on the I/O dielets—a general purpose I/O (GPIO) and a high-speed test I/O. GPIO structures can transfer data at approximately 400 mpps data rate. In order to reduce test time of a multi-dielet module with multiple dielets, the high-speed I/Os are used to support both single data rate (SDR) and double data rate (DDR) speeds. Scan networks in all dielets are timed at a certain frequency. High-speed I/Os can work as fast as twice that of the scan network. With DDR mode, the bandwidth will be increased to 4x (x is the number of I/Os). Test time is reduced by as much as 75% with the same amount of scan data. A clock divider is used to support the high-speed I/Os. High-speed test I/Os can run as fast as 800 MHz with a 1.6 gbps data rate in DDR mode. High-speed test I/Os are built to enable high speed data bandwidth. Each high-speed test I/O is a bidirectional path; it is programmable to be used as either a transmit (TX) driver outbound path or a receive (RX) inbound path. Both TX-driver and receive paths have impedance programmability, allowing high speed signal integrity to transmit data.

In addition to processing structural/scan data as disclosed above, the disclosed method and hardware also processes JTAG data. The processing of the JTAG data uses on physically distinct and separate networks on the I/O dielets and uses physically distinct and separate data paths of the multi-dielet module, e.g., typically physically separate paths on the interposer (e.g., interposer 140/240/340 of FIGS. 1-3). In some embodiments, the JTAG data is compliant with IEEE 1149.1 standards. In the multi-dielet module, each dielet has its own standalone JTAG network and the I/O dielet includes standard IEEE 1149.1 JTAG pins. Due to the limited number of pins on the single package/module, not every dielet can expose its JTAG I/O to its package interface (I/O). In such cases, JTAG chains in the multi-dielet module can be daisy-chained and only one dielet's JTAG I/O is exposed to its package interface (in an I/O dielet but not a non-I/O dielet). Each I/O dielet has its own JTAG interface at a package level (e.g., package interface or I/O). The non-I/O dielets are daisy-chained together with at least one dielet.

Each dielet has its own die index I/O pins that are tied off to a constant in its substrate to represent the dielet ID. At the package level, a die select strap I/O is used to select the target dielets to be tested. All of the dielets that are not targets are bypassed from the JTAG daisy-chain or set to bypass mode if the current dielet is not bypassed. If a dielet is to be bypassed, the entire JTAG network of that dielet is bypassed. The test data in (TDI) and test mode select (TMS) input to the bypassed dielet will be passed to the next dielet via a dielet-to-dielet JTAG interface in the JTAG daisy-chain.

Due to long distance routing in the multi-dielet module substrate (e.g., substate 150/250/350 of FIG. 1/2/3, respectively), a very large wire latency is introduced on the JTAG signals propagating through the multi-dielet module. To improve JTAG timing and reduce testing time, re-timing flops can be placed along the TDI/TMS to test access port (TAP) paths and TAP to test data out (TDO) paths and can be clocked by a nearby buffered test clock (TCK) signal. Routing latency needs to be closely matched. The number of re-timing flops to be added is based on the total routing distance within a dielet. Re-timing flops on the input side of the dielet use positive-edge flops. Re-timing flops on the output side of the dielet use negative-edge flops. This is required to handle potential hold time violations for a cross dielet path due to TCK skew between two dielets. These JTAG path re-timing flops can be bypassed by for IEEE 1149.1 compliance tests.

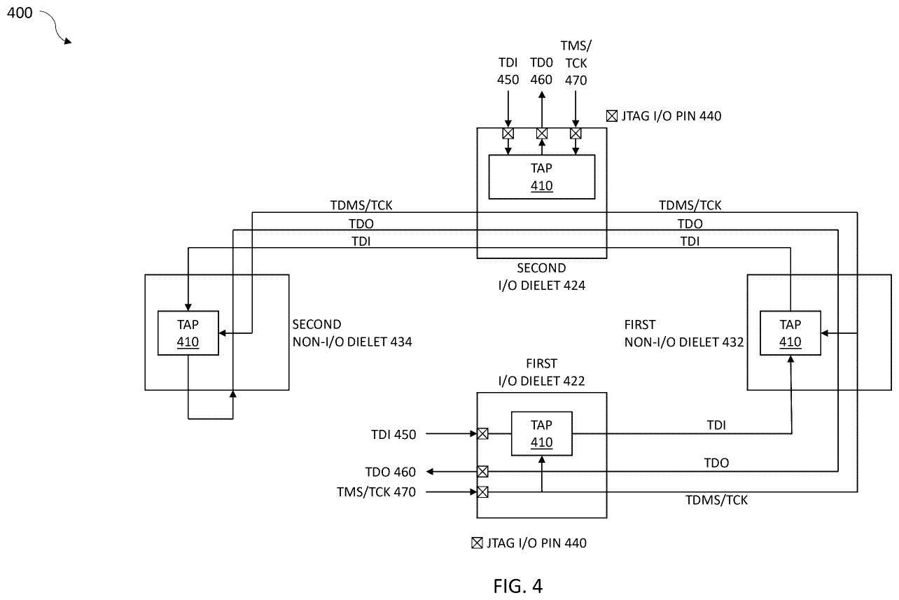

FIG. 4 illustrates an example of signal paths for JTAG data among four dielets of a multi-dielet module 400 where each dielet has its own standalone JTAG network (disclosed above) according to principles of the disclosure. Example multi-dielet module 400 includes four dielets, two I/O dielets 422/424 and two non-I/O dielets 432/434, each similar to I/O dielets 120/220/322/324 and non-I/O dielets 130/230/332/334, respectively, disclosed above in FIGS. 1-3. Of course, the disclosed multi-dielet module can have fewer or more dielets, including fewer or more of both non-I/O dielets and I/O dielets. Each dielet has its own standalone JTAG network that includes its own test access port, e.g., TAP 410. I/O dielets 422/424 include JTAG I/O pins 440 accessible as package I/O pins. These externally accessible package JTAG I/O pins 440 of the I/O dielets 422/424 include pins for TDI 450, TDO 460, and TMS/TCK 470 JTAG signals. First I/O dielet 422 depicted at the bottom of FIG. 4 is a JTAG daisy chain targeted dielet and, as such, TDI signal 450 input into multi-dielet module 400 is applied to TAP 410 of first targeted I/O dielet 422. Also applied to TAP 410 of first targeted I/O dielet 422 are TMS/TCK signals 470. First non-I/O dielet 432 depicted at the right of FIG. 4 is also a targeted dielet in this JTAG daisy chain and receives test data from TAP 410 of first I/O dielet 422 as well as TMS/TCK signals 470.

Second I/O dielet 424 of multi-dielet module 400 depicted at the top of FIG. 4 is not a targeted dielet and, as such, is not in the JTAG daisy chain. As such, test data from TAP 410 of first non-I/O dielet 432 and TMS/TCK signals 470 pass through second I/O dielet 422 on to the next dielet, e.g., second non-I/O dielet 434 depicted on the left of FIG. 4. Here, test data from first non-I/O dielet 432 is applied to TAP 410 of second non-I/O dielet 434 and TMS/TCK signals 470 are also applied to TAP 410 of second non-I/O dielet 434. As second non-I/O dielet 434 is the last dielet of multi-dielet module 400, the output of TAP 410 of second non-I/O dielet 434 becomes test data out (TDO). This TDO signal is fed back through the second I/O dielet 424, first non-I/O dielet 432, and first dielet 422 to JTAG pin 440 of first dielet 422, exiting multi-dielet module 400 as TDO signal 460.

Second I/O dielet 424 has its own external package JTAG I/O pins 440, separate and isolated from the external package JTAG I/O pins 440 of first I/O dielet 422. Of course, if second I/O dielet 424 was a non-I/O dielet, it could not have its own separate and isolated external package JTAG I/O pins 440 since, as disclosed above, non-I/O dielets do not have external package I/O pins. To test the second I/O dielet 424, separate TDI signal 450 is applied from JTAG I/O pin 440 to TAP 410 of second I/O dielet 424, separate TMS/TCK signals 470 are applied from JTAG I/O pin 440 to TAP 410 of second I/O dielet 424, and separate test data out from TAP 410 of second I/O dielet 424 is output from JTAG I/O pin 440 of second I/O dielet 424 as TDO signal 460.

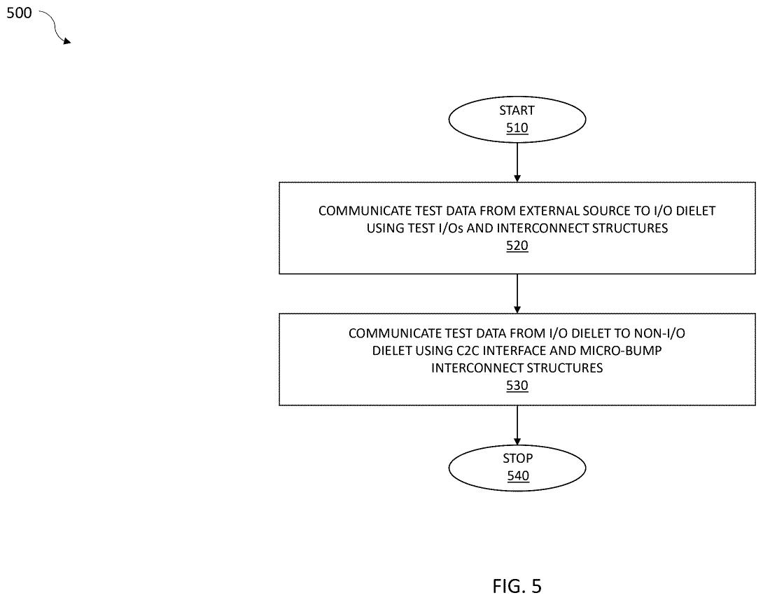

FIG. 5 illustrates a flow diagram 500 of an example of a method of performing a structural/scan test of a multi-dielet module that includes both I/O dielets and non-I/O dielets according to principles of the disclosure. This method starts at step 510. At step 520, test data from a source external to a multi-dielet module is communicated to an I/O dielet (e.g., I/O dielets 120/220/320 disclosed above) using test I/Os (e.g., test I/Os 325 disclosed above) and ball grid array (BGA) interconnect structures (e.g., BGA interconnect structures 160/260/360 disclosed above). The method proceeds to step 530 where test data from the I/O dielet is communicated to a non-I/O dielet (e.g., non-I/O dielets 130/230/330 disclosed above) using a C2C interface (e.g., C2C interface 335 disclosed above) and micro-bump interconnect structures (e.g., micro-bump interconnect structures 170/270/370 disclosed above). The method proceeds to step 540 where the method stops.

In interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

Those skilled in the art to which this application relates will appreciate that other and further additions, deletions, substitutions and modifications may be made to the described embodiments. It is also to be understood that the terminology used herein is for the purpose of describing particular embodiments only, and is not intended to be limiting, since the scope of the present disclosure will be limited only by the claims. Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, a limited number of the exemplary methods and materials are described herein.

What is claimed is:

1. A method to perform structural test of a multi-dielet module that includes both I/O and non-I/O dielets, the method comprising:
communicating structural/scan test data from an external source to at least one I/O dielet using test I/Os and ball-grid array (BGA) interconnect structures, and
communicating the structural/scan test data between the at least one I/O dielet to the non-I/O dielets using a chip-to-chip (C2C) interface and micro-bump interconnect structures.

2. The method as recited in claim 1, further comprising communicating functional data between the at least one I/O dielet and non-I/O dielets using the C2C interface in a functional mode.

3. The method as recited in claim 1, further comprising communicating the structural/scan test data between the at least one I/O dielet and non-I/O dielets using the C2C interface in a bypass mode.

4. The method as recited in claim 1, wherein the structural/scan data is communicated from the external source to a general purpose test I/O (GPIO) of the at least one I/O dielet.

5. The method as recited in claim 4, wherein a data transfer rate for the GPIO is about 400 mbps.

6. The method as recited in claim 1, wherein the structural/scan data is communicated from the external source to a high-speed test I/O of the at least one I/O dielet.

7. The method as recited in claim 6, wherein a data transfer rate for the high-speed test I/O is about 1.6 gbps.

8. The method as recited in claim 6, wherein the high-speed test I/O is a bidirectional path that is:
programmable to be used as either a transmit (TX) driver outbound path or a receive (RX) inbound path; and
has impedance programmability for high speed signal integrity.

9. The method as recited in claim 1, further comprising communicating JTAG data between dielets using a Joint Test Action Group (JTAG) standard and using physically separate networks of the dielets and physically separate interconnect structures.

10. A multi-dielet module comprising:
at least one I/O dielet;
at least one non-I/O dielet;
an interposer, wherein one side of the interposer is connected to the at least one I/O dielet and the at least one non-I/O dielet using micro-bump interconnect structures; and
a substrate connected to another side of the interposer using C4 bumps on one surface of the substrate, wherein the substrate includes ball grid array (BGA) interconnect structures on another surface of the substrate, wherein:
the at least one I/O dielet is configured to allow structural/scan test data from an external source to be communicated through the substrate and interposer to test I/Os of the at least one I/O dielet; and
the at least one I/O dielet is configured to allow the structural/scan test data from the external source to be communicated between the at least one I/O dielet and the at least one non-I/O dielet using a chip-to-chip (C2C) interface of the at least one I/O dielet and the micro-bump interconnect structures of the at least one I/O dielet.

11. The multi-dielet module as recited in claim 10, wherein functional data is communicated between the at least one I/O dielet and the at least one non-I/O dielet using the C2C interface in a functional mode.

12. The multi-dielet module as recited in claim 10, wherein the structural/scan test data is communicated between the at least one I/O dielet and the at least one non-I/O dielet using the C2C interface in a bypass mode.

13. The multi-dielet module as recited in claim 10, wherein the test I/Os of the at least one I/O dielet is a general purpose test I/O (GPIO).

14. The multi-dielet module as recited in claim 13, wherein a data transfer rate for the GPIO is about 400 mbps.

15. The multi-dielet module as recited in claim 10, wherein the test I/Os of the at least one I/O dielet is a high-speed test I/O.

16. The multi-dielet module as recited in claim 15, wherein a data transfer rate for the high-speed test I/O is about 1.6 gbps.

17. The multi-dielet module as recited in claim 15, wherein the high-speed test I/O is a bidirectional path that is:
programmable to be used as either a transmit (TX) driver outbound path or a receive (RX) inbound path; and
has impedance programmability for high speed signal integrity.

18. The multi-dielet module as recited in claim 10, wherein JTAG data is communicated between dielets using a Joint Test Action Group (JTAG) standard and using physically separate networks of the dielets, physically separate micro-pump interconnect structures, and physically separate paths of the interposer.

19. The multi-dielet module as recited in claim 10, further comprising multiplexers (MUXs) of the at least one I/O dielet and the at least one non-I/O dielet configured to be controlled to either transmit or receive:
functional data between the at least one I/O dielet and the at least one non-I/O dielet; or
the structural/scan test data between the at least one I/O dielet and the at least one non-I/O dielet.

20. A non-I/O dielet, comprising:
a plurality of bond pads configured to receive interconnect structures; and
a plurality of chip-to-chip (C2C) interfaces configured to communicate with at least one other non-I/O dielet or at least one I/O dielet, wherein structural/scan test data is communicated between the least one I/O dielet and the at least one other non-I/O dielet using at least one of the C2C interfaces and the interconnect structures.

21. The non-I/O dielet as recited in claim 20, wherein the interconnect structures are micro-bump interconnect structures.

22. The non-I/O dielet as recited in claim 20, wherein functional data is communicated between the non-I/O dielet and the at least one other non-I/O dielet or at least one I/O dielet using the at least one of the C2C interfaces in a functional mode.

23. The non-I/O dielet as recited in claim 20, wherein the structural/scan test data is communicated between the non-I/O dielet and the at least one other non-I/O dielet or at least one I/O dielet using the at least one of the C2C interfaces in a bypass mode.

24. The non-I/O dielet as recited in claim 20, further comprising a multiplexer (MUX) configured to be controlled to either transmit or receive:
functional data between the non-I/O dielet and the at least one other non-I/O dielet or at least one I/O dielet or transmit; or
the structural/scan test data between the non-I/O dielet and the at least one other non-I/O dielet or at least one I/O dielet.

25. An I/O, dielet, comprising:
a plurality of bond pads configured to receive ball grid array (BGA) interconnect structures;
a plurality of test I/Os, each connected to a corresponding one of the plurality of bond pads configured to receive the BGA interconnect structures;
a plurality of other bond pads configured to receive micro-bump interconnect structures; and
a plurality of chip-to-chip (C2C) interfaces, each connected to a corresponding one of the plurality of other bond pads configured to receive the micro-bump interconnect structures, configured to communicate with at least one non-I/O dielet, wherein:
structural/scan test data is received by the test I/Os of the I/O dielet; and
the plurality of C2C interfaces communicate the structural/scan test data to the at least one non-I/O dielet using at least one of the C2C interfaces and the micro-bump interconnect structures.

26. The I/O dielet as recited in claim 25, wherein functional data is communicated between the I/O dielet and the at least one non-I/O dielet using the plurality of C2C interfaces in a functional mode.

27. The I/O dielet as recited in claim 25, wherein the structural/scan test data is communicated between the I/O dielet and the at least one non-I/O dielet using the plurality of C2C interfaces in a bypass mode.

28. The I/O dielet as recited in claim 25, wherein a portion of the plurality of test I/Os are general purpose test I/Os (GPIO).

29. The I/O dielet as recited in claim 28, wherein a data transfer rate for the GPIOs is about 400 mbps.

30. The I/O dielet as recited in claim 25, wherein another portion of the test I/Os are high-speed test I/Os.

31. The I/O dielet as recited in claim 30, wherein a data transfer rate for the high-speed test I/Os is about 1.6 gbps.

32. The I/O dielet as recited in claim 30, wherein the high-speed test I/Os are a bidirectional path that is:
programmable to be used as either a transmit (TX) driver outbound path or a receive (RX) inbound path; and
has impedance programmability for high speed signal integrity.

33. The I/O dielet as recited in claim 25, wherein JTAG data is communicated between dielets using a Joint Test Action Group (JTAG) standard and using physically separate networks of the dielets and physically separate micro-pump interconnect structures.

34. The I/O dielet as recited in claim 25, further comprising a multiplexer (MUX) configured to be controlled to either transmit or receive:
functional data between the I/O dielet and the at least one non-I/O dielet; or
the structural/scan test data between the at least one I/O dielet and the at least one non-I/O dielet.
